(19) United States
(12) Patent Application Publication
(10) Pub. No.: US 2005/0258448 A1
(43) Pub. Date: Nov. 24, 2005

(54) Thyristor component with improved blocking capabilities in the reverse direction

(76) Inventors: Reiner Barthelmess, Soest (DE); Uwe Kellner-Werdehausen, Leutenbach (DE); Franz-Josef Niedernostheide, Munster (DE); Hans-Joachim Schulze, Ottobrunn (DE)

Correspondence Address: Andreas Grubert;Baker Botts L.L.P., One Shell Plaza, 910 Louisiana, Houston, TX, 77002-4995, US

(21) Appl. No.: 11/116,919

(22) Filed: Apr. 28, 2005

Related U.S. Application Data
(63) Continuation of application No. PCT/EP03/12005, filed on Oct. 29, 2003.

(30) Foreign Application Priority Data
Oct. 30, 2002 (DE) DE 102 50 608.6

(51) Int. Cl. H01L 29/74

(52) U.S. Cl. 257/107

(57) ABSTRACT

A thyristor comprises a semiconductor body with a front and back face, an edge, a first semiconductor zone, embodied in the region of the rear face and a second semiconductor zone, adjacent to the first semiconductor zone, whereby the edge has a bevelled embodiment in the region of the transition between the first and second semiconductor zones, at least one third semiconductor zone, arranged in the region of the front face of the semiconductor body and at least one fourth semiconductor zone, arranged between the at least one third semiconductor zone and the second semiconductor zone. The fourth semiconductor zone terminates before the edge in the lateral direction of the semiconductor body, in order to reduce the amplification of a parasitic bipolar transistor formed in the region of the edge by the fourth semiconductor zone, the second semiconductor zone and the first semiconductor zone.

### CROSS REFERENCE TO RELATED APPLICATION

This application is a continuation of copending International Application No. PCT/EP03/12005 filed Oct. 29, 2003 which designates the United States, and claims priority to German application no. 102 50 608.6 filed Oct. 30, 2002.

### TECHNICAL FIELD OF THE INVENTION

The present invention relates to a thyristor component.

### BACKGROUND OF THE INVENTION

A thyristor component of this type is sufficiently known and described for example in EP 0 039 509 A2 or in U.S. Pat. No. 4,079,403. The first semiconductor zone in the region of the rear side of the semiconductor body, which is usually p-doped, forms the so-called anodal emitter of the thyristor component, the adjoining, complementarily doped second semiconductor zone the anodal base, the at least one third semiconductor zone arranged in the region of the front side forms the cathodal emitter and the fourth semiconductor zone arranged between said cathodal emitter and the anodal base forms the cathodal base of the component.

Thyristor components are distinguished in a sufficiently known manner by their properties of being able to block voltages in the non-driven state both in the so-called forward direction, that is to say upon application of a positive voltage between the anodal emitter and the cathodal emitter, and in the reverse direction, that is to say upon application of a negative voltage between the anodal emitter and the cathodal emitter. What is critical in this case for the dielectric strength of the component in the reverse direction is the dielectric strength of the pn junction between the rear-side anodal emitter and the adjoining anodal base, which is critically determined by the dimensions and the doping concentration of the anodal base, which is also referred to as the n-type base zone of the component.

In this case, the edge region of the component in particular is critical with regard to the dielectric strength. In order to increase the dielectric strength in the edge region, it is known to bevel the edge in the region of said pn junction in such a way that the cross-sectional area of the semiconductor zones decreases in the region of the pn junction in the direction of the more weakly doped semiconductor zone, usually the n-type base zone. A positive bevel is the expression used in this context. Such a bevel for increasing the dielectric strength in the edge region of pn junctions is described extensively in Baliga: “Power Semiconductor Devices”, PWS Publishing, ISBN 0-534-94098-6, pages 103 et seq. and 116 et seq. The positive bevel has the effect of curving the potential lines in the edge region toward the cathode side, thereby reducing the field strength at the surface. However, this curvature of the potential lines has the effect of reducing a neutral zone, which is not taken up by a space charge zone upon application of a reverse voltage, in the edge region of the n-type base zone.

The sequence of the anodal emitter zone, the anodal base zone, or n-type base zone, doped complementarily thereto and the cathodal base zone results in the formation of a pnp bipolar transistor in the thyristor component. The reduction of the neutral zone in the edge region on account of the positive bevel of the edge brings about an amplified injection of said bipolar transistor at the edge, the presence of said bipolar transistor adversely influencing the reverse dielectric strength of the component. It holds true in this case that the reverse dielectric strength is lower, the greater the gain factor of said bipolar transistor. If the gain factor of said transistor is αₚₙₚ then the reverse dielectric strength is proportional to 1-αₚₙₚ. Consequently, said bipolar transistor counteracts the reverse dielectric strength of the component.

### SUMMARY OF THE INVENTION

Therefore, it is an object of the present invention to provide a thyristor component of the type mentioned in the introduction in which the gain of said bipolar transistor is reduced in the edge region in order to increase the reverse dielectric strength.

This object can be achieved by a thyristor component comprising a semiconductor body having a front side, a rear side and an edge, a first semiconductor zone of a first conductivity type, which is formed in the region of the rear side, and a second semiconductor zone of a second conductivity type adjoining the first semiconductor zone, the edge being formed such that it runs in a beveled manner in the region of the junction between the first and second semiconductor zones, at least one third semiconductor zone of the second conductivity type arranged in the region of the front side of the semiconductor body, and at least one fourth semiconductor zone of the first conductivity type, which is arranged between the at least one third semiconductor zone and the second semiconductor zone, wherein the fourth semiconductor zone ends before the edge in the lateral direction of the semiconductor body in order to reduce the gain of a parasitic bipolar transistor formed by the fourth semiconductor zone, the second semiconductor zone and the first semiconductor zone in the region of the edge.

The object can also be achieved by a thyristor component comprising a semiconductor body having a front side, a rear side and an edge, a first semiconductor zone of a first conductivity type formed in the region of the rear side, a second semiconductor zone of a second conductivity type adjoining the first semiconductor zone, wherein the edge runs in a beveled manner in the region of the junction between the first and second semiconductor zones, at least one third semiconductor zone of the second conductivity type arranged in the region of the front side of the semiconductor body, and at least one fourth semiconductor zone of the first conductivity type arranged between the at least one third semiconductor zone and the second semiconductor zone and ending before the edge in the lateral direction of the semiconductor body.

At least one field ring of the first conductivity type can be arranged in the region of the front side between the fourth semiconductor zone and the edge, wherein the field ring is separated from the fourth semiconductor zone by a section of the second semiconductor zone and is arranged at a distance from the edge. At least two field rings can be provided, which are separated from one another in each case by a section of the second semiconductor zone. The field rings can be arranged in floating fashion. The doping concentration in the fourth semiconductor zone can decrease in the lateral direction of the semiconductor body in the edge region in the direction of the edge. A boundary zone of the second conductivity type can be formed in the region of the front side and the edge, which boundary zone is formed at a distance from the fourth semiconductor zone. A boundary zone of the second conductivity type can be formed in the region of the front side and the edge, which boundary zone is formed at a distance from the at least one field ring. The front side of the semiconductor body can be formed in planar fashion.

In the case of the thyristor component according to the invention, provision is made for forming the fourth semiconductor zone that forms the cathodal base of the thyristor component such that it ends before the edge in the lateral direction of the semiconductor body in order thereby to reduce the gain of the bipolar transistor formed by said cathodal base zone, the first semiconductor zone, which forms the anodal emitter, and the second semiconductor zone, which forms the anodal base or the n-type base zone, in the edge region of the component. The n-type base zone thus extends in sections as far as the front side of the semiconductor body in order to “cut off” the cathodal base zone from the edge region of the component.

However, this procedure of causing the cathodal base zone to end before the edge of the component in principle reduces the forward dielectric strength of the component, so that additional measures are preferably provided in order to counteract this reduction of the forward dielectric strength.

Thus, in one embodiment of the thyristor component according to the invention, at least one field ring of the first conductivity type is arranged in the region of the front side of the semiconductor body between the cathodal base zone and the edge, the field ring being separated from the cathodal base zone by a section of the n-type base zone and being arranged at a distance from the edge. In accordance with a further embodiment, at least two field rings arranged at a distance from one another are provided, which surround the cathodal base zone in the region of the front side of the semiconductor body.

The field rings are arranged in floating fashion, by way of example, it being possible additionally to provide field plates for influencing the profile of the electric field above the field rings.

In a further exemplary embodiment, in order to increase the dielectric strength in the forward direction, it is provided that at least one semiconductor zone of the first conductivity type that is doped more weakly than the cathodal base zone is provided in a manner adjoining the cathodal base zone in the lateral direction. Preferably, a plurality of such semiconductor zones are present, the doping concentration of which decreases proceeding from the cathodal base zone in the direction of the edge. These more weakly doped zones on the one hand influence the potential line profile in the blocking case in the forward direction, in order to increase the dielectric strength in the forward direction, and on the other hand these zones, owing to their lower doping, reduce the gain factor of the parasitic bipolar transistor formed by the anodal emitter zone, the n-type base zone and said semiconductor zones in the edge region of the component.

Preferably, a boundary zone or field stop zone of the second conductivity type, which is doped more heavily than the drift zone, is formed between the front side and the edge in the n-type base zone.

In the thyristor component according to the invention, the front side of the semiconductor body is preferably formed in planar fashion without a negative bevel up to the edge. Dispensing with such a negative bevel reduces the outlay during fabrication compared with those semiconductor components in which a negative bevel is provided in the region of the front side in order to increase the forward dielectric strength. In the case of the component according to the invention, the increase in the forward dielectric strength is achieved by means of the field rings or the doping of the cathodal base zone that decreases toward the edge.

### BRIEF DESCRIPTION OF THE DRAWING

The semiconductor component according to the invention is explained in more detail below with reference to exemplary embodiments in figures.

FIG. 1 shows a cross section through a thyristor component according to the invention in accordance with a first embodiment with field rings arranged in the region of the front side of the component.

FIG. 2 shows a cross section through a semiconductor component according to the invention in accordance with a second embodiment with a more weakly doped semiconductor zone adjoining a cathodal base zone in the direction of an edge.

### DETAILED DESCRIPTIONS OF THE PREFERRED EMBODIMENTS

In the figures, unless specified otherwise, identical reference symbols designate identical parts and semiconductor regions with the same meaning.

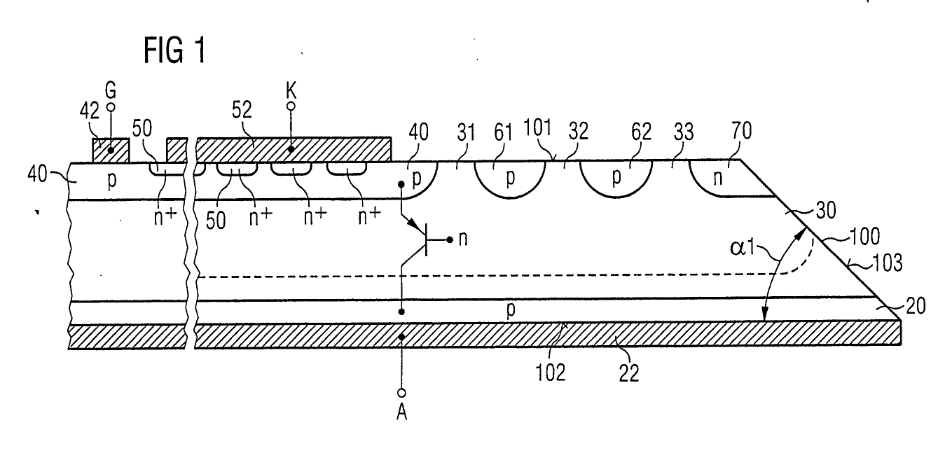

FIG. 1 shows a cross section through a thyristor component according to the invention in accordance with a first embodiment of the invention.

The component comprises a semiconductor body 100 comprising a front side 101, a rear side 102 and an edge 103 running between the front side 101 and the rear side 102. The semiconductor body 100 comprises a semiconductor zone 20 which is p-doped in the exemplary embodiment, but which usually is not necessarily formed as a continuous layer in the region of the rear side 102. Said first semiconductor zone 20 is adjoined, in the direction of the front side 101, by an n-doped second semiconductor zone or semiconductor layer 30. Heavily n-doped third semiconductor zones 50 are provided in the region of the front side 101, and are separated from the second semiconductor zone 30 by a p-doped fourth semiconductor zone 40. The first semiconductor zone 20 forms the anodal emitter of the thyristor component and is contact-connected by means of an anode electrode 22. The second semiconductor zone 30 forms the anodal base or n-type base of the thyristor component, which is also referred to as the n-type base zone. The third semiconductor zones, which are jointly contact-connected by a cathode electrode 52, form the cathodal emitter and the fourth semiconductor zone 40 forms the cathodal base of the thyristor component. In order to improve the forward dielectric strength, cathode short circuits are usually provided in the region of the cathodal emitter zones.

The cross-sectional illustration in FIG. 1 merely shows the edge region of the thyristor component, which, by way of example, is formed symmetrically and in circular fashion in plan view; for the sake of completeness, in order to afford a better understanding, FIG. 1 additionally illustrates a detail which is at a greater distance from the edge and in which the cathodal base zone 40 is contact-connected by means of a gate electrode 42, via which the thyristor can be triggered. It goes without saying that it is possible to use any other triggering structures desired, in particular contactless structures for the light triggering of the thyristor.

The thyristor in accordance with FIG. 1 is operated in the forward direction upon application of a positive voltage between the anode terminal A and the cathode terminal K, while it is operated in the reverse direction upon application of a negative voltage between the anode terminal A and the cathode terminal K. What is critical for the dielectric strength in the reverse direction is the pn junction between the anodal emitter 20 and the n-type base or the n-type base zone 30 and also the current gain factor αₚₙₚ of a bipolar transistor formed by the cathodal base 40, the n-type base zone 30 and the anodal emitter 20. In order to increase the dielectric strength in the edge region, the edge 103 runs beveled at an angle α1 in the region of said pn junction in such a way that the cross-sectional area of the semiconductor body 100 decreases from the more heavily doped anodal emitter 20 in the direction of the more weakly doped n-type base zone 30. A positive bevel of the edge 103 is the expression used in this context. This results, in a known manner, in a curvature of the potential line profile in the n-type base zone in the edge region 103 upward, as is illustrated in dashed fashion for a potential line in the reverse blocking case in FIG. 1, and a reduction of the field strength on the edge surface.

The circuit symbol of the pnp bipolar transistor formed by the cathodal base 40, the n-type base zone 30 and the anodal emitter 20 is depicted in FIG. 1. The current gain of said bipolar transistor counteracts the dielectric strength of the thyristor in the reverse direction, in which case this transistor would experience an amplified injection in the edge region owing to the curved potential line profile there.

Therefore, the invention provides for configuring the cathodal base zone 40 such that it ends before the edge 103 in the lateral direction of the semiconductor body 100. In order to counteract a reduction of the forward dielectric strength that results from this, field rings 61, 62 are provided in the case of the exemplary embodiment in accordance with FIG. 1, which field rings are arranged between the cathodal base 40 and the edge 103 in the region of the front side 101 and annularly surround the cathodal base 40 in a plane perpendicular to the cross-sectional plane illustrated. Between one of the field rings 61 and the cathodal base 40, and respectively between the two field rings 61, 62, sections 31, 32 of the n-type base zone 30 extend as far as the front side 101 of the semiconductor body. These field rings 61, 62 have the task of influencing the potential line profile in the blocking case in the forward direction in such a way as to prevent high degrees of curvature of said potential line profile, which has a favorable effect on the forward dielectric strength. The course of the boundary of the space charge zone in the blocking case in the forward direction is depicted in dash-dotted fashion in FIG. 1.

In order to delimit the space charge zone in the edge region, a boundary zone or field stop zone 70 which is doped more heavily than the n-type base zone 30 is provided between the front side 101 and the edge 103, and is arranged at a distance from the nearest field ring 62.

In a manner that is not illustrated in any greater detail, field plates may furthermore be provided above the front side 101 of the semiconductor body 100, which field plates additionally influence the potential line profile in the semiconductor body 100.

The edge structure with the field rings and the stop zone 70 as illustrated in FIG. 1 can be fabricated by means of sufficiently known methods of semiconductor technology. For this purpose, during the fabrication of the p-type base, the edge is firstly masked, a mask subsequently or previously being applied to the front side 101 in the edge region, which mask leaves free the sections of the field rings to be produced, a doping with p-type dopant atoms subsequently being effected. Boron in particular is suitable as a dopant material. The mask comprises a semiconductor oxide or a resist, by way of example.

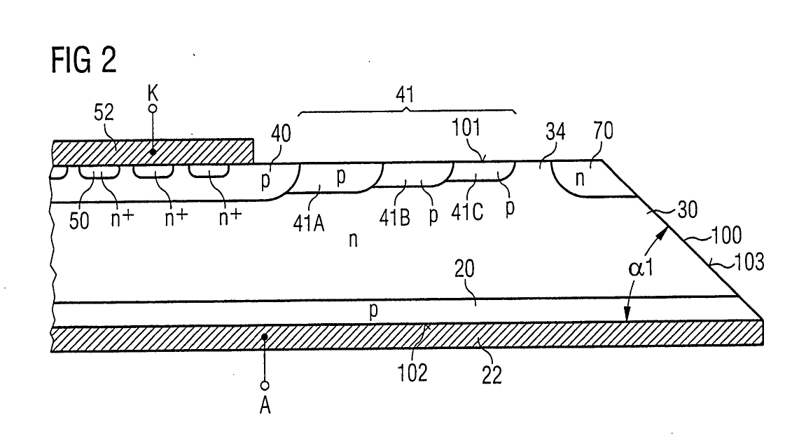

FIG. 2 shows a further exemplary embodiment of a thyristor component according to the invention in the edge region in cross section.

Instead of the field rings, a p-doped semiconductor zone 41 is provided in the case of this exemplary embodiment, and is formed between the cathodal base 40 and the edge 103 in the region of the front side 101. Said semiconductor zone 41 is doped more weakly than the cathodal base 40 and directly adjoins said cathodal base 40. The semiconductor zone 41 is preferably formed such that its doping concentration decreases in the direction of the edge 103, which may be achieved for example by providing a plurality of mutually adjoining semiconductor regions 41A, 41B, 41C, the doping concentration decreasing from semiconductor zone to semiconductor zone in the direction of the edge 103. Preferably, the extent of the semiconductor zone 41 in the vertical direction likewise decreases with increasing proximity to the edge 103.

In the n-type base zone 30, a more heavily doped boundary zone 70 is provided between the front side 101 and the edge 103, a section 34 of the n-type base zone 30 extending as far as the front side 101 of the semiconductor body 100 between said boundary zone 70 and the semiconductor zone 41.

The function of the semiconductor zone 41, in a manner corresponding to the function of the field rings in accordance with FIG. 1, is to influence the curvature profile of the potential lines in the n-type base zone 30 in such a way as to reduce high degrees of curvature in favor of an improved forward dielectric strength. The doping concentration of the semiconductor zone 41, which adjoins the cathodal base 40, is lower than that of the cathodal base 40, so that a parasitic bipolar transistor formed by the semiconductor zone 41, the n-type base zone 30 and the anodal emitter 20 in the edge region has a low gain factor, which becomes apparent in a positive manner with regard to the reverse dielectric strength.

Finally, it is pointed out that, in the case of the thyristor component according to the invention, it is possible to form the front side 101 of the semiconductor body 100 in planar fashion up to the edge 103. However, it goes without saying that it is also possible to negatively bevel the front side 101 in the direction of the edge 103 in a known manner in order to achieve an additional improvement in the forward dielectric strength.

1. A thyristor component comprising:
a semiconductor body having a front side, a rear side and an edge, a first semiconductor zone of a first conductivity type, which is formed in the region of the rear side, and a second semiconductor zone of a second conductivity type adjoining the first semiconductor zone, the edge being formed such that it runs in a beveled manner in the region of the junction between the first and second semiconductor zones,
at least one third semiconductor zone of the second conductivity type arranged in the region of the front side of the semiconductor body, and at least one fourth semiconductor zone of the first conductivity type, which is arranged between the at least one third semiconductor zone and the second semiconductor zone, wherein
the fourth semiconductor zone ends before the edge in the lateral direction of the semiconductor body in order to reduce the gain of a parasitic bipolar transistor formed by the fourth semiconductor zone, the second semiconductor zone and the first semiconductor zone in the region of the edge.

2. The thyristor component as claimed in claim 1, wherein at least one field ring of the first conductivity type is arranged in the region of the front side between the fourth semiconductor zone and the edge, which field ring is separated from the fourth semiconductor zone by a section of the second semiconductor zone and is arranged at a distance from the edge.

3. The thyristor component as claimed in claim 2, wherein at least two field rings are provided, which are separated from one another in each case by a section of the second semiconductor zone.

4. The thyristor component as claimed in claim 1, wherein the field rings are arranged in floating fashion.

5. The thyristor component as claimed in claim 1, wherein the doping concentration in the fourth semiconductor zone decreases in the lateral direction of the semiconductor body in the edge region in the direction of the edge.

6. The thyristor component as claimed in claim 1, wherein a boundary zone of the second conductivity type is formed in the region of the front side and the edge, which boundary zone is formed at a distance from the fourth semiconductor zone.

7. The thyristor component as claimed in claim 1, wherein a boundary zone of the second conductivity type is formed in the region of the front side and the edge, which boundary zone is formed at a distance from the at least one field ring.

8. The thyristor component as claimed in claim 1, wherein the front side of the semiconductor body is formed in planar fashion.

9. A thyristor component comprising:
a semiconductor body having a front side, a rear side and an edge,
a first semiconductor zone of a first conductivity type formed in the region of the rear side,
a second semiconductor zone of a second conductivity type adjoining the first semiconductor zone, wherein the edge runs in a beveled manner in the region of the junction between the first and second semiconductor zones,
at least one third semiconductor zone of the second conductivity type arranged in the region of the front side of the semiconductor body, and
at least one fourth semiconductor zone of the first conductivity type arranged between the at least one third semiconductor zone and the second semiconductor zone and ending before the edge in the lateral direction of the semiconductor body.

10. The thyristor component as claimed in claim 9, wherein at least one field ring of the first conductivity type is arranged in the region of the front side between the fourth semiconductor zone and the edge, which field ring is separated from the fourth semiconductor zone by a section of the second semiconductor zone and is arranged at a distance from the edge.

11. The thyristor component as claimed in claim 9, wherein the doping concentration in the fourth semiconductor zone decreases in the lateral direction of the semiconductor body in the edge region in the direction of the edge.

12. The thyristor component as claimed in claim 9, wherein a boundary zone of the second conductivity type is formed in the region of the front side and the edge, which boundary zone is formed at a distance from the at least one field ring.

13. A method for manufacturing a thyristor component comprising the steps of:
providing a semiconductor body having a front side, a rear side and an edge,
forming a first semiconductor zone of a first conductivity type in the region of the rear side,
forming a second semiconductor zone of a second conductivity type adjoining the first semiconductor zone, wherein the edge being formed such that it runs in a beveled manner in the region of the junction between the first and second semiconductor zones,
forming at least one third semiconductor zone of the second conductivity type arranged in the region of the front side of the semiconductor body, and
forming at least one fourth semiconductor zone of the first conductivity type arranged between the at least one third semiconductor zone and the second semiconductor zone and ending before the edge in the lateral direction of the semiconductor body.

14. The method as claimed in claim 13, further comprising the step of forming at least one field ring of the first conductivity type in the region of the front side between the fourth semiconductor zone and the edge, which field ring is separated from the fourth semiconductor zone by a section of the second semiconductor zone and is arranged at a distance from the edge.

15. The method as claimed in claim 14, wherein at least two field rings are formed, which are separated from one another in each case by a section of the second semiconductor zone.

16. The method as claimed in claim 13, wherein the field rings are arranged in floating fashion.

17. The method as claimed in claim 13, wherein the doping concentration in the fourth semiconductor zone decreases in the lateral direction of the semiconductor body in the edge region in the direction of the edge.

18. The method as claimed in claim 13, wherein a boundary zone of the second conductivity type is formed in the region of the front side and the edge, which boundary zone is formed at a distance from the fourth semiconductor zone.

19. The method as claimed in claim 13, wherein a boundary zone of the second conductivity type is formed in the region of the front side and the edge, which boundary zone is formed at a distance from the at least one field ring.

20. The method as claimed in claim 13, wherein the front side of the semiconductor body is formed in planar fashion.
